(19) United States
(12) Patent Application Publication
(10) Pub. No.: US 2003/0218218 A1
(43) Pub. Date: Nov. 27, 2003

(54) SRAM cell with reduced standby leakage current and method for forming the same

(76) Inventors: Samir Chaudhry, Weston, FL (US); Goh Komoriya, Allentown, PA (US); William John Nagy, Orlando, FL (US); Ranbir Singh, Orlando, FL (US)

Correspondence Address: CHRISTIE, PARKER & HALE, LLP, 350 WEST COLORADO BOULEVARD, SUITE 500, PASADENA, CA, 91105, US

(21) Appl. No.: 10/152,971

(22) Filed: May 21, 2002

(51) Int. Cl. H01L 29/76

(52) U.S. Cl. 257/391

(57) ABSTRACT

An SRAM cell within a semiconductor device includes p-channel transistors with increased threshold voltages to suppress standby leakage current in the SRAM cell. Existing processing operations already being used to form the semiconductor device, are used to produce the SRAM p-channel devices to have higher threshold voltages than logic p-channel devices also included within the semiconductor device. The processing operations used to form thicker gate oxides for transistors in the I/O portion of the same semiconductor device, may be used to form increased gate oxide thicknesses within the SRAM p-channel transistors. The SRAM p-channel transistors may include a gate oxide that is thicker than the gate oxides of the SRAM n-channel transistors and the logic p-channel transistors. In another embodiment, the gates of the SRAM p-channel transistors may be counterdoped with n-type impurities to produce an effectively greater gate oxide thickness due to poly depletion.

### FIELD OF THE INVENTION

The present invention relates most generally to semiconductor devices and methods for forming the same. More particularly, the present invention relates to an SRAM (Static Random Access Memory) cell with reduced standby leakage current and a method for forming the same.

### BACKGROUND OF THE INVENTION

SRAMs are the fastest semiconductor memories. Memory devices such as SRAMs store digital information (or data) in terms of bits, or binary digits (ones or zeros). Modern digital systems use memory devices to store and retrieve large quantities of digital data at electronic speeds. Memory devices are therefore advantageously included in logic or other semiconductor devices in high-scale integration schemes. As such, when an SRAM cell or cells are included within a semiconductor device, it is critical that the SRAM cell or cells function properly and efficiently. SRAMs function, in part, by holding charge at the storage node of the SRAM. The ability to store charge is therefore important to SRAM performance. Standby leakage currents in the SRAM cell compromise the ability of the SRAM to store charge and adversely affect the performance of the SRAM. When an unacceptably high standby leakage current is experienced in the SRAM cell, the cell may be nonfunctional and, when the SRAM cell is included within a semiconductor device such as an integrated circuit, the functionality of the overall integrated circuit may be destroyed. High standby leakage currents also create unexpected voltage drops, decrease device reliability and decrease battery life in mobile components.

It is therefore desirable to suppress standby leakage current and, more particularly, to suppress standby leakage current without adversely affecting performance.

### SUMMARY OF THE INVENTION

To achieve these and other objects, and in view of its purposes, the present invention addresses the shortcomings of conventional attempts to reduce standby leakage current in SRAM cells, and provides an SRAM cell in a semiconductor device, the SRAM cell including p-channel transistors and n-channel transistors. The device is characterized by the p-channel transistors of the SRAM cell having an average gate oxide thickness which is greater than the average gate oxide thickness of the n-channel transistors of the SRAM cell.

According to another exemplary embodiment, the present invention provides a semiconductor device comprising an SRAM cell including p-channel transistors and n-channel transistors. The device is characterized by the n-channel transistors each including an n-channel gate formed of a semiconductor material and having an n-type impurity at a first concentration level therein. The p-channel transistors each include a p-channel gate formed of the semiconductor material and having both a p-type impurity at a second concentration level therein and the n-type impurity at the first concentration level therein.

According to another exemplary embodiment, the present invention provides an integrated circuit including both an SRAM cell and logic portions. Each of the SRAM cell and the logic portions include p-channel transistors. The integrated circuit is characterized by the p-channel transistors of the SRAM cell having a higher threshold voltage than similar p-channel transistors of the logic portion of the integrated circuit.

According to yet another exemplary embodiment, the present invention provides a method for forming an SRAM cell having reduced leakage characteristics. The method includes providing a semiconductor device including an SRAM cell and a logic section, the SRAM cell including SRAM p-channel transistors and SRAM n-channel transistors and the logic section including p-channel transistors. The method provides for performing processing operations such that the SRAM p-channel transistors have an average threshold voltage that is greater than the average threshold voltage of the logic p-channel transistors.

### BRIEF DESCRIPTION OF THE DRAWING

The present invention is best understood from the following detailed description when read in conjunction with the accompanying drawing. It is emphasized that, according to common practice, the various features of the drawing are not to scale. On the contrary, the dimensions of the various features and the relative dimensions and locations of the features are arbitrarily expanded or reduced for clarity. Included in the drawing are the following figures.

FIG. 1 is a schematic circuit diagram of a conventional SRAM cell; and

FIG. 2 is a cross-sectional view showing portions of various transistors formed in the same semiconductor device according to the present invention.

### DETAILED DESCRIPTION OF THE INVENTION

SRAM cells are advantageously included in integrated circuits and other semiconductor devices that also include logic portions and input/output (I/O) portions. The performance of an SRAM cell is primarily determined by n-channel devices. The p-channel devices typically do not impact performance significantly, but, instead, are added primarily to hold charge at the storage node, the gate of the pull down transistor. The p-channel devices are therefore not required to be high performance devices. The present invention is directed to increasing the threshold voltage, Vₜ, of the p-channel transistors and therefore lowering SRAM standby leakage without adversely affecting cell performance. The present invention provides for increasing the Vₜ of the p-channel transistors of the SRAM cell by using processing operations already used to form the integrated circuit or other semiconductor device which includes the SRAM cell.

Various technologies are available in the art that provide methods for forming semiconductor devices that include SRAM cells and logic portions. A principle of the present invention is that, for the various methods of forming semiconductor devices that include SRAM cells and logic portions, the processing operations used to form the semiconductor device may be used to form SRAM p-channel transistors that have an average threshold voltage greater than the average threshold voltage of the logic p-channel transistors.

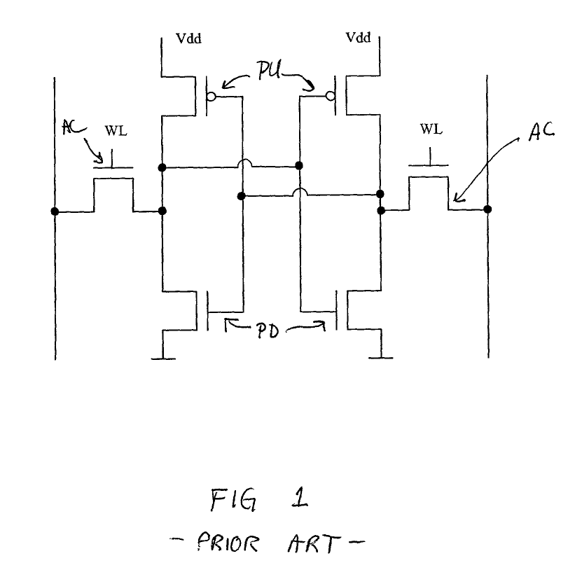

FIG. 1 is a schematic circuit diagram of a conventional SRAM cell. In an SRAM, the off current of one pull-up (PU) device, one pull-down (PD) device and one access (AC) device determines the leakage of the cell. The PU devices are p-channel transistors provided in the SRAM cell to supply charge loss at the storage node, which is primarily due to junction leakage or leakage through the device itself in its off state. The storage node is the gate of the pull-down PD device. The pull-down PD and access AC devices are typically n-channel transistors. The AC devices are coupled to the write lines (WL). Since the p-channel PU transistor is provided primarily to supply charge loss at the storage node, the PU transistors need not be high performance devices. Therefore, by increasing the threshold voltage of the p-channel PU device, the leakage current, I_{off}, is reduced without affecting cell performance. The increase in Vₜ may represent an increase relative to conventional p-channel transistors formed in an SRAM cell using the same technology, or an increase relative to p-channel transistors formed in the logic portion of the same semiconductor device and using the same technology. In well designed SRAM transistors, an order of magnitude decrease in I_{off} is achieved for approximately an 80 millivolt increase in Vₜ. Conventional attempts to increase the threshold voltage of the pull-up PU device in the SRAM have focused on implanting the substrate of the PU transistor using an additional implantation step and additional masking steps to isolate the PU devices. The present invention provides for increasing the threshold voltage of the p-channel PU transistor without using additional masking and implanting processing operations dedicated solely to increasing the Vₜ of the p-channel SRAM transistors. Rather, the present invention utilizes existing processing operations that are already used to form the integrated circuit or other semiconductor device which includes the SRAM cell. The present invention finds application in various technologies used to form semiconductor devices that include SRAM cells.

According to one exemplary embodiment, the SRAM cell is included in a semiconductor device which also includes a logic portion and an input-output (I/O) section, and the p-channel transistors of the SRAM cell are formed to include a thicker gate oxide than the n-channel transistors of the SRAM cell, and a thicker gate oxide than the p-channel transistors of the logic portions of the semiconductor device. The processing operations already in place and used to form thicker oxides in other portions of the semiconductor device, such as the gate oxides for the I/O transistors, may be used to form the thicker gate oxides for the SRAM p-channel transistors.

According to another exemplary embodiment, the present invention provides for increasing the threshold voltage of the p-channel devices in the SRAM cell through an effectively thicker gate oxide formed by counterdoping the p-gates of the p-channel transistors in the SRAM with dopant impurities that are also used to dope the n-gates of the n-channel transistors. The gates of both the n-channel transistors and the p-channel transistors are commonly formed of the same semiconductor material such as polysilicon. The effectively greater oxide thickness is the result of increased gate poly depletion (when polysilicon is the gate material of choice). According to this exemplary embodiment, then, existing process operations necessary to form the device, namely, the masking and implantation process operations used to dope the gates of the n-channel transistors, are used to counterdope the gates of the SRAM p-channel devices, and additional processing operations dedicated to increasing the Vₜ of the SRAM p-channel devices, are not needed. According to another exemplary embodiment in which the power supply, V_{dd} (see FIG. 1) is large enough, for example, greater than 2.5 volts, the gates of the p-channel transistors in the SRAM cell, may skip the p-gate doping process and be implanted with the n-type dopant impurities that are also introduced into the n-gates of the n-channel transistors. Again, this advantage can be achieved without additional processing operations.

Increased Gate Oxide Thickness

It is well known in the art that, for transistors formed using the same technology and including the same structural dimensions and physical characteristics, as gate oxide thickness increases, the corresponding threshold voltage increases accordingly, and, when the transistor of interest is a p-channel transistor in an SRAM cell, the standby leakage current, I_{off}, decreases. Most submicron technologies use dual gate oxides for core logic and I/O devices. Typically, p- and n-channel transistors of the core logic device include the same gate oxide thickness, even though they are formed within substrate areas that include different dopant impurity species and probably using different impurity concentrations. The dopant impurity regions in which the respective n-channel and p-channel devices are formed, are commonly referred to as tub implant areas. According to one exemplary embodiment, each of the n-channel and p-channel transistors of the logic device may be formed according to a particular technology (which may be designated using any of various terminologies such as a “1.5 Volt technology”) and may each include the same targeted gate oxide thickness. When an SRAM cell is also included in the semiconductor logic device, each of the n-channel and p-channel transistors formed within the SRAM cell will conventionally have the same gate oxide thicknesses as one another and also the same gate oxide thickness as the—and p-channel devices formed in the logic portion. Transistors formed in the I/O portion of the same conventional semiconductor device, however, will generally be formed using a different technology and to include a greater gate oxide thickness. For example, when exemplary transistors formed in the SRAM and logic portions include gate oxide thicknesses of 24 Å, the I/O transistors may be formed to include gate oxide thicknesses of desirably 50 Å in the conventional device. Such gate oxide thicknesses are intended to be exemplary only, and according to other exemplary embodiments, each of the above-discussed thicknesses may differ and the relative gate oxide thicknesses may similarly differ. Furthermore, it should be understood that, in each case, when a gate oxide thickness is given for a particular type of transistor (for example, the SRAM n-channel transistor) such gate oxide thickness is understood to be the average such thickness of multiple such transistors formed in the device. Furthermore, while the oxide thickness values are given in physical dimensions, one of ordinary skill in the art will appreciate that the effective electrical gate oxide thickness may differ from the physical gate oxide thickness.

The present invention provides for modifying such a conventional device by selectively supplying a thicker gate oxide to the p-channel devices of the SRAM cell by using processing operations already being used to form thicker gate oxides for transistors formed in other areas of the semiconductor device such as in the I/O portion. Most submicron technologies use dual gate oxides for core logic and I/O devices and therefore include operations which produce different gate oxide thicknesses in different areas. According to this exemplary embodiment, the gate oxide thicknesses of the p-channel devices in the SRAM cell, are formed to essentially the same thicknesses as the transistors in the I/O portion. In one exemplary embodiment, gate oxides of 24 Å are formed for SRAM n-channel transistors and logic p- and n-channel transistors, and gate oxides of 50 Å are formed on transistors in the I/O portion and the SRAM p-channel transistors of the same chip. According to this embodiment of the present invention, the gate oxide thickness of the p-channel devices in the SRAM cell is increased relative to the gate oxide thickness that would otherwise be formed according to conventional technology, and is greater than the gate oxide thickness of the n-channel transistors in the SRAM cell and the gate oxide thicknesses of the p-channel transistors in the logic portion. In this manner, existing processing operations already being used in the formation of the semiconductor device which includes the SRAM, namely, the masking, etching, re-oxidation sequence used to form thicker gate oxides in the I/O portion, is used to increase the Vₜ of the p-channel transistors within the SRAM, and an additional set of processing operations dedicated to increasing the threshold voltage, is not required.

According to an exemplary embodiment, the formation of different gate oxide thicknesses in the same semiconductor device may be effectuated by first forming an oxide film substantially over the entire substrate upon which the semiconductor device is being formed. Typically, a plurality of substantially identical semiconductor devices such as integrated circuits, are simultaneously formed on the substrate. Thermal oxidation or various other suitable dielectric deposition processes may be used to form the oxide film. In an exemplary embodiment, the substrate may be a silicon wafer and a thermal oxidation process used to form a thermal SiO₂ film. In an exemplary embodiment, the original oxide thickness may be 45 Å but may range from 10-200 Å according to various exemplary embodiments. Next, a masking operation is used to mask sections in which it is desired to form the thicker gate oxide. Conventional masking materials such as photoresists and conventional lithographic techniques may be used to mask the designated areas by forming an etch resistant masking material thereon. According to conventional technologies, only devices formed in the input/output area are masked, and thereby designated to include a thicker gate oxide, and the transistors in the SRAM and logic areas are not masked, as they are formed to include the thinner gate oxide. The present invention, however, provides for masking the SRAM p-channel transistor areas so that they are also formed to include the relatively thick gate oxide as discussed below.

After the areas designated to have thicker gate oxides formed therein, are masked, a conventional etching operation may be used to essentially strip the entire thickness of the originally formed oxide film from areas which were not masked while the masked portions are unaffected. After the masking material, such as a photoresist, is removed using conventional and suitable means, a thermal oxidation process is carried out. According to one exemplary embodiment, a thermal oxidation process may be carried out to grow approximately 24 Å of oxide in the stripped and unmasked areas while simultaneously increasing the oxide thickness of the original oxide film in the previously masked area from 45 to 50 Å. The original gate oxide thickness of 45 Å, the relatively thin gate oxide thickness of 24 Å, and the relatively thick gate oxide thickness of 50 Å are intended to be exemplary only, and other oxide thicknesses may be used in other exemplary embodiments. One of ordinary skill in the art will appreciate that oxide growth does not occur linearly in time and, by varying the thermal oxidation growth time and conditions, oxide films of various thicknesses can be formed. In this manner, different relative thicknesses between the relatively thin gate oxides and the relatively thick gate oxides can be achieved. According to one exemplary embodiment, the relatively thin gate oxide may range from 13-32 Å, and the relatively thick gate oxide may range from 45-80 Å, but other thickness ranges and relative thicknesses may be used. According to one exemplary embodiment, the relatively thick gate oxide may be twice as thick as the relatively thin gate oxide.

The present invention utilizes the oxide film formation/masking/etching/thermal growth process sequence conventionally used to differentiate the gate oxide thicknesses between I/O and other devices, and applies this differential oxide thickness concept to the SRAM by masking areas in which the p-channel devices, such as PU transistors, are being formed in the SRAM. No processing operations are added. The photomask used in the masking process is simply manufactured to produce masked areas in regions where the gates of the SRAM p-channel transistors are to be formed. In this manner, the p-channel transistors formed in the SRAM will be formed to include a greater gate oxide thickness than the n-channel transistors formed in the SRAM and the p-channel transistors formed in the logic area. The SRAM p-channel devices may include the relatively thick gate oxide of thicknesses described above, and the SRAM n-channel devices and logic p-channel devices may include the relatively thin gate oxide having thicknesses as described above. Devices in the I/O portion will advantageously include the relatively thick gate oxide thickness.

A principle of this aspect of the present invention is that, for the various methods of forming semiconductor devices that include SRAM cells and logic portions, the processing operations used to form the semiconductor device may be used to form SRAM p-channel transistors having an average gate oxide thickness greater than average gate oxide thicknesses of the logic p-channel transistors and the SRAM n-channel transistors.

As a result of the relatively thick gate oxide, the p-channel transistors in the SRAM may include a higher Vₜ than similar p-channel transistors formed in the logic area and higher than the same devices would have if formed to include the relatively thin gate oxide. In one exemplary embodiment, the average Vₜ of p-channel devices formed in a logic area may be 0.4 volts while the p-channel devices formed in the SRAM may include an average Vₜ of 0.65 volts. In other exemplary embodiments, the increased threshold voltage of the p-channel devices formed in the SRAM may range from 0.5-1.0 volts, while the threshold voltage of the same devices formed with the relatively thin gate oxide, including p-channel transistors formed in the logic area, may be 0.3-0.5 volts.

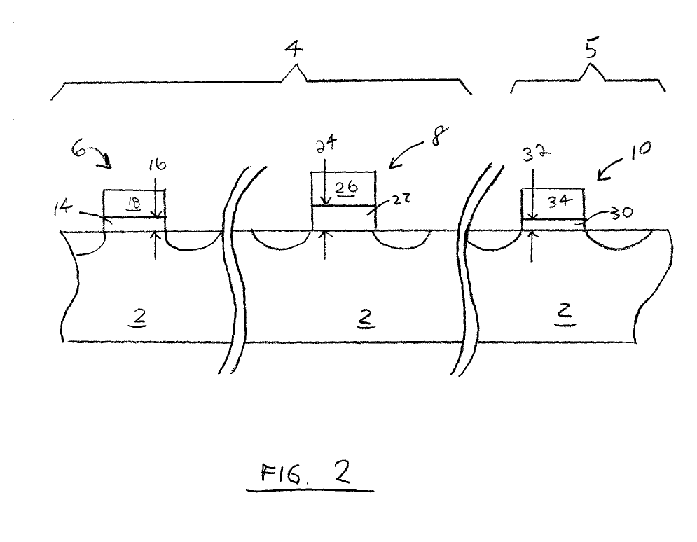

FIG. 2 is a cross-sectional view showing SRAM n-channel transistor 6 and SRAM p-channel transistor 8 formed within SRAM cell 4 of a semiconductor device. The semiconductor device may be an integrated circuit. Also illustrated is logic p-channel transistor 10 formed within logic portion 5 of the same semiconductor device. Each of the transistors are formed on substrate 2, although the p-channel and n-channel devices are formed within different substrate regions (not shown), including different impurity species and likely different impurity concentrations. It can be seen that gate oxide 22 of SRAM p-channel transistor 8 includes gate oxide thickness 24, which is greater than thickness 16 of gate oxide 14 of SRAM n-channel transistor 6 and also greater than thickness 32 of gate oxide 30 of logic p-channel transistor 10. Gate oxide 22 may be considered relatively the thick gate oxide, including thicknesses described above, while gate oxides 14 and 30 may be considered relatively thin gate oxides with thicknesses 16 and 32 being substantially the same and as described above. Although not illustrated, transistors formed in I/O portion of the same semiconductor device will generally include relatively thick gate oxide 22, but the above principles may also be applied in the I/O portion to produce different oxide thicknesses.

Doping the p-Channel Gates with n-Type Impurities

Transistors formed in semiconductor devices typically include a gate formed of a conductive or semiconductive material. Polysilicon, or polycrystalline silicon, is such a commonly used gate material. Polysilicon provides the advantage that it can be doped with n-type impurity species to become an n-type material or it can be doped with p-type dopant impurity species to become a p-type material, as desired. Furthermore, the conductivity and resistance of the polysilicon material can be altered by the type and concentration of impurity species added. Various techniques may be used to dope the polysilicon, that is, introduce impurity species therein. For simplicity and clarity, the following discussion will be based upon polysilicon being the gate material, although it should be understood that other materials may be used in other exemplary embodiments. Similarly, the gate may be a composite gate structure formed of a polysilicon film subjacent a subsequently formed film. An aspect of the present invention is the doping, or introduction of impurity species, into the polysilicon gate and after the polysilicon portion of the gate is formed according to this exemplary embodiment, the additional, optional gate layers may be subsequently added over the polysilicon gate portion to form the composite gate structure. N-channel transistors commonly include an n-gate, that is, a polysilicon gate material that is doped with n-type impurity species. Similarly, p-channel transistors commonly include p-gates, polysilicon gate material doped with p-type impurity species. In advanced technologies, n-gates are doped substantially only with n-type dopant impurities and p-gates are doped substantially only with p-type dopant impurities. For simplicity, the gates of n-channel transistors will therefore be referred to as n-gates and the gates of p-channel transistors as p-gates, although they may be “counterdoped” as described below.

Conventional techniques such as diffusion and ion implantation may be used to introduce the dopant impurity species into the polysilicon material. Boron is commonly used as a p-type dopant impurity and phosphorous and/or arsenic may be used as n-type dopant impurities, although other dopant impurity species may be used in other exemplary embodiments.

In conventional devices, n-type dopant impurities are introduced into gates designated to be n-gates by masking the p-gates during the processing operation or operations used to introduce the n-type dopant impurities, such that the n-type dopant impurities are blocked from entering the masked portions. Similarly, in conventional devices, p-type dopant impurities are introduced into gates designated to be p-gates by masking the n-gates during the processing operation or operations used to introduce the p-type dopant impurities. Ion implantation or other suitable techniques may be used to introduce dopant impurities into the exposed, or unmasked, areas and conventional masking techniques and materials may be used. The masking materials include photosensitive materials such as photoresist, dielectrics, and other materials capable of preventing the dopant impurity from entering the masked polysilicon gate during the process or processes used to introduce the dopant impurities into the desired gates.

P-channel transistors formed in the logic portion are desirably high performance devices. Such devices are therefore formed to have as low a threshold voltage as possible. This is achieved, in part, by forming their gate materials to include a high concentration of p-type dopant impurities, known as a p⁺ region. While such a structure and threshold voltage is favored for the high performance logic p-channel transistors, the present invention provides for counterdoping the p-channel transistors in the SRAM by introducing n-type dopant impurities into the gates of these transistors which also include the p⁺ dopant impurity concentration. This counterdoping lowers the effective doping level of the gates of the SRAM p-channel transistors which increases poly depletion creating a higher effective gate oxide thickness and therefore a higher Vₜ.

The present invention provides for counterdoping the gates of the p-channel transistors of the SRAM cell with the n-type dopant impurities. In an exemplary embodiment, the n-type dopant impurities may be introduced into the SRAM p-channel transistors using the processing operations already used to dope the n-gates. No additional processing operations are required in this embodiment. In another exemplary embodiment, a separate series of processing operations may be used. According to one exemplary embodiment, the sequence of processing operations used to introduce the p-type dopant impurities into p-gates throughout the semiconductor device (such as the high performance logic p-channel transistors), are used to dope the gates of the p-channel transistors of the SRAM cell and the same set of processing operations used to introduce n-type dopant impurities into the n-gates of the n-channel transistors are used to also dope the gates of the p-channel transistors of the SRAM cell. The doping operations may take place in either sequence. This is accomplished by manufacturing the photomasks used to mask designated areas during the n-type doping process such that the SRAM p-channel transistors are not masked. In this manner, the n-type dopant impurities are introduced into the gates of the SRAM p-channel transistors during the process operations already used to introduce n-type dopant impurities into n-gates. Since one doping operation is used, both the n-gates and the counterdoped gates of the SRAM p-channel transistors, include the same n-type impurity concentration. The SRAM p-channel transistors are also doped during the operations used to introduce p-type dopant impurities into p-gates such as the gates of the logic p-channel transistors. Since one doping operation is used, both the logic p-channel transistors and the SRAM p-channel transistors are formed to include the same p-type impurity concentration. The logic p-channel devices include substantially only this impurity at this concentration.

In an exemplary embodiment, the n-type dopant impurity such as arsenic or phosphorous may be added to an impurity concentration within the range of 10¹⁹-10²⁰ atoms/cm³. P-type dopant impurities may be introduced to include a concentration within the range of 10²²-10²³ atoms/cm³ in an exemplary embodiment, but each of the aforementioned impurity concentrations may vary according to other exemplary embodiments. The p-type dopant impurity concentration may be chosen to produce a p⁺ region, advantageous for the high-performance logic p-channel devices. In this manner, the gates of the SRAM p-channel transistors which are conventionally p-doped gates, include both n-type and p-type impurities unlike the logic p-channel transistors, and therefore have an overall impurity concentration different than the corresponding logic p-channel transistors. The p-type material is effectively counterdoped with the n-type impurity species. The counterdoped p-gates of the SRAM p-channel devices thereby have a lower effective dopant impurity concentration and an effectively thicker gate oxide thickness as a result of increased gate poly depletion. The effectively thicker gate oxide thickness produces a higher threshold voltage and a correspondingly lower I_{off}, standby leakage current.

According to another exemplary embodiment in which the power supply, V_{dd} (see FIG. 1) is large enough, for example, greater than 2.5 volts, the gates of the p-channel transistors in the SRAM cell may skip the p-gate doping process and be doped essentially only with the n-type dopant impurities that are also introduced into the n-gates. This exemplary method can be carried out using existing processing steps, and also provides a lower effective dopant impurity concentration in the p-channel transistors of the SRAM, based on the representative, relative n-type and p-type dopant impurity concentrations given above. Therefore, a higher Vₜ results.

In an exemplary embodiment, the increased threshold voltage of the SRAM p-channel transistors may be within the range of 0.5 to 1.0 Volt while the threshold voltage of the logic p-channel transistors in the same semiconductor device may lie within the range of 0.3 to 0.5 Volts. In one exemplary embodiment, the average Vₜ of p-channel devices formed in a logic area may be 0.4 volts while the p-channel devices formed in the SRAM may include an average Vₜ of 0.65 volts. These threshold voltages are intended to be exemplary only and the absolute and relative values of the threshold voltages may vary in other exemplary embodiments according to various device characteristics including the relative amounts of dopant impurities introduced as described above.

The fundamental concepts of the present invention may be used separately or in combination, to increase the threshold voltage of the SRAM p-channel transistors.

The preceding merely illustrates the principles of the invention. It will thus be appreciated that those skilled in the art will be able to devise various arrangements which, although not explicitly described or shown herein, embody the principles of the invention and are included within its scope and spirit. Furthermore, all examples and conditional language recited herein are principally intended expressly to be only for pedagogical purposes and to aid in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and the functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of the present invention is embodied by the appended claims.

What is claimed is:

1. A semiconductor device comprising an SRAM cell including p-channel transistors and n-channel transistors and characterized by said p-channel transistors having a first average gate oxide thickness and said n-channel transistors having a second average gate oxide thickness, said first average gate oxide thickness being greater than said second average gate oxide thickness.

2. The semiconductor device as in claim 1, wherein said p-channel transistors include at least one pull-up transistor.

3. The semiconductor device as in claim 1, in which said first average gate oxide thickness is approximately two times said second average gate oxide thickness.

4. The semiconductor device as in claim 1, in which said n-channel transistors each include an n-channel gate formed of a semiconductor material and having an n-type impurity at a first concentration level therein and said p-channel transistors each include a p-channel gate formed of said semiconductor material and having boron as a p-type impurity at a second concentration level therein and said n-type impurity at said first concentration level therein, wherein said n-type impurity comprises one of phosphorous and arsenic, said first concentration level lies within the range of 10¹⁹ to 10²⁰ atoms/cm³, and said second concentration level lies within the range of 10²² to 10²³ atoms/cm³.

5. The semiconductor device as in claim 1, wherein said p-channel transistors each include p-channel gates and said n-channel transistors each include n-channel gates, each of said n-channel gates and said p-channel gates including substantially only an n-type impurity therein.

6. The semiconductor device as in claim 1, in which said semiconductor device is an integrated circuit further comprising a logic portion including logic n-channel transistors and logic p-channel transistors, each having a third average gate oxide thickness, said first average gate oxide thickness being greater than said third average gate oxide thickness.

7. The semiconductor device as in claim 6, in which said third average gate oxide thickness is substantially equal to said second average gate oxide thickness.

8. The semiconductor device as in claim 6, in which said first average gate oxide thickness is approximately two times said third average gate oxide thickness.

9. The semiconductor device as in claim 6, in which said integrated circuit further comprises an input/output (I/O) portion including I/O transistors having a fourth average gate oxide thickness being substantially equal to said first average gate oxide thickness.

10. The semiconductor device as in claim 1, in which said semiconductor device is an integrated circuit further comprising a logic portion containing logic p-channel transistors, said logic p-channel transistors having an average logic threshold voltage being lower than an average SRAM threshold voltage of said p-channel transistors included within said SRAM cell.

11. A semiconductor device comprising an SRAM cell including p-channel transistors and n-channel transistors and characterized by said n-channel transistors each including an n-channel gate formed of a semiconductor material and having an n-type impurity at a first concentration level therein and said p-channel transistors each including a p-channel gate formed of said semiconductor material and having a p-type impurity at a second concentration level therein and said n-type impurity at said first concentration level therein.

12. The semiconductor device as in claim 11, wherein said n-type impurity comprises one of phosphorous and arsenic, said first concentration level lies within the range of 10¹⁹ to 10²⁰ atoms/cm³, said p-type impurity comprises boron and said second impurity concentration level lies within the range of 10²² to 10²³ atoms/cm³.

13. The semiconductor device as in claim 11, in which said semiconductor device is an integrated circuit further comprising a logic portion including logic p-channel transistors therein, each having a gate formed of said semiconductor material and including substantially only said p-type impurity at said second concentration level, as an impurity therein.

14. An integrated circuit comprising an SRAM cell and a logic portion, each of said SRAM cell and said logic portion including p-channel transistors therein, said integrated circuit characterized by said p-channel transistors of said SRAM cell having a higher average threshold voltage than said p-channel transistors of said logic portion.

15. The integrated circuit as in claim 14, in which at least one of said p-channel transistors of said SRAM cell comprises a pull-up transistor.

16. The integrated circuit as in claim 14, in which said p-channel transistors of said SRAM cell have an average threshold voltage within the range of 0.5 to 1.0 volts and said p-channel transistors of said logic portion have an average threshold voltage within the range of 0.3 to 0.5 volts.

17. The integrated circuit as in claim 16, further characterized by said p-channel transistors of said SRAM cell having an average gate oxide thickness being greater than an average gate oxide thickness of said p-channel transistors of said logic portion, said average gate oxide thickness of said p-channel transistors of said logic portion being within the range of 13-32 Å.

18. The integrated circuit as in claim 14, in which said p-channel transistors of said logic portion include transistor gates formed of a semiconductor material and including substantially only boron as an impurity species therein, and including a boron concentration within the range of 10²²-10²³ atoms/cm³, and said p-channel transistors of said SRAM cell include transistor gates formed of said semiconductor material and including boron as an impurity species therein at said boron concentration, and one of phosphorous and arsenic as a further impurity species therein at a further impurity species concentration within the range of 10¹⁹-10²⁰ atoms/cm³.

19. A method for forming an SRAM cell having reduced leakage characteristics, comprising:
providing a semiconductor device including an SRAM cell and a logic section, said SRAM cell including SRAM p-channel transistors and SRAM n-channel transistors and said logic section including logic p-channel transistors; and
performing processing operations such that said SRAM p-channel transistors have an average threshold voltage greater than an average threshold voltage of said logic p-channel transistors.

20. The method as in claim 19, in which said performing processing operations includes forming relatively thick gate oxides within said SRAM p-channel transistors and forming relatively thin gate oxides within said SRAM n-channel transistors and said logic p-channel transistors.

21. The method as in claim 20, in which said semiconductor device is formed on a substrate and said performing processing operations includes forming an original oxide film on said substrate, masking areas in which said relatively thick gate oxide is desired, removing said original oxide film from other areas, then growing a further oxide film in said masked areas and in said other areas, thereby substantially simultaneously forming said relatively thick gate oxides and said relatively thin gate oxides.

22. The method as in claim 20, in which said semiconductor device includes an input/output (I/O) section and said providing a semiconductor device includes forming said semiconductor device and forming said relatively thick gate oxides within at least some transistors in said I/O section.

23. The method as in claim 19, in which said performing processing operations includes introducing a p-type dopant impurity into gates of said SRAM p-channel transistors and gates of said logic p-channel transistors, and introducing an n-type dopant impurity into gates of said SRAM n-channel transistors and said gates of said SRAM p-channel transistors.

24. The method as in claim 23, in which said introducing a p-type dopant impurity includes introducing said p-type dopant impurity at a concentration within the range of 10²²-10²³ atoms/cm³ and in which said introducing said n-type dopant impurity includes introducing said n-type dopant impurity at a concentration within the range of 10¹⁹-10²⁰ atoms/cm³.

25. The method as in claim 19, in which said performing processing operations includes introducing a p-type dopant impurity into gates of said logic p-channel transistors and introducing an n-type dopant impurity into gates of each of said SRAM n-channel transistors and said SRAM p-channel transistors.

26. The method as in claim 19, in which said providing a semiconductor device includes forming said semiconductor device and said performing processing operations includes utilizing processing operations included within said forming a semiconductor device.
